(19) United States
(12) Patent Application Publication
(10) Pub. No.: US 2005/0202667 A1
(43) Pub. Date: Sep. 15, 2005

(54) Electrochemical fabrication methods incorporating dielectric materials and/or using dielectric substrates

(75) Inventors: Adam L. Cohen, Los Angeles, CA (US); Gang Zhang, Monterey Park, CA (US); Fan-Gang Tseng, Hsinchu (TW)

Correspondence Address: MICROFABRICA INC.;DENNIS R. SMALLEY, 1103 W. ISABEL ST., BURBANK, CA, 91506, US

(73) Assignee: University of Southern California

(21) Appl. No.: 11/028,957

(22) Filed: Jan. 3, 2005

Related U.S. Application Data
(63) Continuation-in-part of application No. 10/309,521, filed on Dec. 3, 2002.
(60) Provisional application No. 60/338,638, filed on Dec. 3, 2001.
(60) Provisional application No. 60/340,372, filed on Dec. 6, 2001.
(60) Provisional application No. 60/379,133, filed on May 7, 2002.
(60) Provisional application No. 60/379,182, filed on May 7, 2002.
(60) Provisional application No. 60/379,184, filed on May 7, 2002.
(60) Provisional application No. 60/415,374, filed on Oct. 1, 2002.
(60) Provisional application No. 60/379,130, filed on May 7, 2002.
(60) Provisional application No. 60/392,531, filed on Jun. 27, 2002.

(51) Int. Cl. H01L 21/4763; H01L 21/44

(52) U.S. Cl. 438/622; 438/619; 438/618; 438/631

(57) ABSTRACT

Various embodiments are directed to the electrochemical fabrication of multilayer mesoscale or microscale structures which are formed using at least one conductive structural material, at least one conductive sacrificial material, and at least one dielectric material. In some embodiments the dielectric material is a UV-curable photopolymer. In other embodiments, electrochemically fabricated structures are formed on dielectric substrates.

### RELATED APPLICATIONS

This application is a continuation in part of U.S. patent application Ser. No. 10/309,521, filed Dec. 3, 2002 and this application claims benefit of U.S. Provisional Patent Application Nos. 60/468,979 and 60/469,053, both filed on May 7, 2003. The Ser. No. 10/309,521 application claims benefit of U.S. Provisional Patent Application Nos.: 60/338,638 filed on Dec. 3, 2001; 60/340,372 filed on Dec. 6, 2001; 60/379,133 filed on May 7, 2002; 60/379,182 filed on May 7, 2002; 60/379,184 filed on May 7, 2002; 60/415,374 filed on Oct. 1, 2002; 60/379,130 filed on May 7, 2002 and 60/392,531 filed on Jun. 27, 2002. Each of the above noted priority applications are hereby incorporated herein by reference as if set forth in full.

### FIELD OF THE INVENTION

The present invention relates generally to the field of Electrochemical Fabrication and the associated formation of three-dimensional structures (e.g. microscale or mesoscale structures). In particular, it relates to electrochemical fabrication methods that incorporate dielectric materials into the layers of the structure being formed and/or that form structures on dielectric substrates.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
(1) A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, Aug. 1998.
(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
(3) A. Cohen, “3-D Micromachining by Electrochemical Fabrication”, Micromachine Devices, March 1999.
(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., Apr. 1999.
(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
(8) A. Cohen, “Electrochemical Fabrication (EFAB™)”, Chapter 19 of The MEMS Handbook, edited by Mohamed Gad-EI-Hak, CRC Press, 2002.
(9) Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

The '637 patent teaches the locating of a plating base onto a substrate in preparation for electroplating materials onto the substrate. The plating base is indicated as typically involving the use of a sputtered film of an adhesive metal, such as chromium or titanium, and then a sputtered film of the metal that is to be plated. It is also taught that the plating base may be applied over an initial sacrificial layer of material on the substrate so that the structure and substrate may be detached if desired. In such cases after formation of the structure, the plating base may be patterned and removed from around the structure and then the sacrificial layer under the plating base may be dissolved to free the structure. Substrate materials mentioned in the '637 patent include silicon, glass, metals, and silicon with protected processed semiconductor devices. A specific example of a plating base includes about 150 angstroms of titanium and about 300 angstroms of nickel, both of which are sputtered at a temperature of 160° C. In another example it is indicated that the plating base may consist of 150 angstroms of titanium and 150 angstroms of nickel where both are applied by sputtering.

The '630 patent further indicates that the electroplating methods and articles disclosed therein allow fabrication of devices from thin layers of materials such as, e.g., metals, polymers, ceramics, and semiconductor materials. It further indicates that although the electroplating embodiments described therein have been described with respect to the use of two metals, a variety of materials, e.g., polymers, ceramics and semiconductor materials, and any number of metals can be deposited either by the electroplating methods therein, or in separate processes that occur throughout the electroplating method. It indicates that a thin plating base can be deposited, e.g., by sputtering, over a deposit that is insufficiently conductive (e.g., an insulating layer) so as to enable subsequent electroplating. It also indicates that multiple support materials (i.e. sacrificial materials) can be included in the electroplated element allowing selective removal of the support materials.

Even though electrochemical fabrication as taught and practiced to date, has greatly enhanced the capabilities of microfabrication, and in particular added greatly to the number of metal layers that can be incorporated into a structure and to the speed and simplicity in which such structures can be made, and even to the incorporation of some dielectric materials, room for and a need for enhancing dielectric incorporation and/or building on dielectric substrates exists.

### SUMMARY OF THE INVENTION

It is an object of some embodiments of the invention to provide enhanced electrochemical fabrication methods for forming three-dimensional structures on dielectric substrates and/or for incorporating dielectrics into the formation of individual layers.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

In a first aspect of the invention, a process for forming a multilayer three-dimensional structure, that includes at least one conductive structural material and at least one dielectric material, including: (a) forming and adhering a layer of material to a previously formed layer and/or to a substrate, wherein the layer includes a desired pattern of at least one structural material, a grid pattern of a dielectric material, and a gird pattern of a conductive sacrificial material; and (b) repeating the forming and adhering operation of (a) a plurality of times to build up the three-dimensional structure from a plurality of adhered layers.

In a second aspect of the invention, a process for forming a multilayer three-dimensional structure that includes at least one conductive structural material and at least one dielectric material further includes: (a) forming and adhering a layer of material to a previously formed layer and/or to a substrate, wherein the layer includes a desired pattern of at least one structural material, a desired pattern of a dielectric material, and a desired pattern of a conductive sacrificial material; and (b) repeating the forming and adhering operation of (a) a plurality of times to build up the three-dimensional structure from a plurality of adhered layers; wherein the dielectric material is deposited via an electrophoretic deposition operation.

In a third aspect of the invention, a fabrication process for forming a multi-layer three-dimensional structure on a dielectric substrate, includes: (a) depositing a first adhesion layer onto the substrate and a first seed layer onto the first adhesion layer; (b) using an adhered mask, selectively depositing and adhering a conductive structural material to a selected portion of the seed layer material; (c) removing only a portion of seed layer material and adhesion layer material that is not coated over by the structural material; (d) blanket depositing a second adhesion layer material and a second seed layer material over the substrate, exposed portion of the first seed layer material, and the structural material; (e) blanket depositing sacrificial material; (f) planarizing the deposited materials to set the height of a first layer and to expose the structural material; (g) forming additional layers of the structure; and (h) releasing the structural material from the sacrificial material and removing the second seed layer and the second adhesion layer to reveal the completed structure.

In a fourth aspect of the invention, a fabrication process for forming a multi-layer three-dimensional structure wherein at least three materials are used in the formation of the structure, includes: (a) forming and adhering a first layer of material to the substrate via at least one seed layer material and/or at least one adhesion layer material, wherein the first layer comprises at least one region of a structural material and at least one region of a sacrificial material; (b) forming a subsequent layer from a plurality of materials that are adhered to previously deposited materials and repeating formation of subsequent layers until the structure is formed from a plurality of adhered layers; wherein the at least one seed layer material and/or the at least one adhesion layer material separating at least a portion of the structural material of the first layer from the dielectric substrate is different from a seed layer material and/or an adhesion layer material that separates at least a portion of the sacrificial material of the first layer from the dielectric material of the substrate, and wherein at least one of a structural material or at least one of a sacrificial material is selectively patterned using an adhered mask.

Further aspects of the invention will be understood by those of skill in the art upon reviewing the teachings herein. Other aspects of the invention may involve apparatus that can be used in implementing one or more of the above method aspects of the invention. These other aspects of the invention may provide various combinations of the aspects, embodiments, and associated alternatives explicitly set forth herein as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-1G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIG. 5 provides a block diagram of some basic operations that form part of a first group of embodiments of the invention.

FIG. 6 provides a block diagram of some basic operations that form part of a second group of embodiments of the invention.

FIG. 7 provides a block diagram of a process according to a third group of embodiments, which are based on the general process of FIG. 5, where a conductive structural material is deposited followed by electrophoretic deposition of a conductively coated dielectric material and then a deposition of a sacrificial conductive material (to fill voids or pores within the electrophoretically deposited material).

FIG. 8 provides a block diagram of a process according to a fourth group of embodiments, which are based on the general process of FIG. 6, where a conductive structural material is deposited, an electrophoretic deposition of material occurs and a sacrificial conductive material is deposited to fill the voids in the electrophoretically deposited material and to fill regions over the substrate where only the sacrificial conductive material is to be located.

FIG. 9 provides a block diagram of a process according to a fifth group of embodiments, which are based on the general process of FIG. 6, where an electrophoretic selective deposition of a material occurs, followed by deposition of a sacrificial conductive material to fill voids or pores within the electrophoretically deposited material and to fill regions over the substrate where only the sacrificial conductive material is to be located, and followed by deposition of a conductive structural material.

FIG. 10 provides a block diagram of a process according to a sixth group of embodiments, which are based on the general process of FIG. 6, where a sacrificial conductive material is selectively deposited, a selective electrophoretic deposition of a conductively coated dielectric material occurs, a second selective deposition of sacrificial material occurs, and then a deposition of a conductive structural material occurs.

FIG. 11 provides a block diagram of a process according to a seventh group of embodiments, which are based on the general process of FIG. 6, where a conductive structural material is selectively deposited, a blanket deposition of conductive sacrificial material occurs, an etching operation creates voids in the sacrificial material where a dielectric material is to be located, a blanket electrophoretic deposition of a conductively coated dielectric material occurs, and finally a second selective deposition of sacrificial material occurs.

FIG. 12A depicts a grid structure that may be used in forming multilayer structures that contain both conductive and non-conductive materials where the grid is formed from two complementary patterns, one of a structural dielectric material and the other of a sacrificial conductive material (the desired structure which is to be supported by grid is not shown).

FIGS. 12B and 12C, respectively, schematically depict a side view of first layer of a structure and its lattice on a substrate and a top view of that same layer where the layer includes a conductive structural material, a conductive sacrificial material, and a structural dielectric material.

FIGS. 12D and 12E, respectively, schematically depict a side view of first and second layer of a structure and its lattice on a substrate and a top view of the second layer where the layer includes a conductive structural material, a conductive sacrificial material, and a structural dielectric material and where the grid of FIGS. 12D and 12E has been shifted from that of FIGS. 12B and 12C.

FIGS. 13A-13D, respectively correspond to FIGS. 12A-12D with the exception that the grid has been tailored such that no dielectric material exists in the lower left hand corner of each cross-section.

FIG. 14 presents a block diagram of a process according to an eighth group of embodiments of the present invention where a grid of dielectric structural material and sacrificial conductive material is formed so as to allow deposition of conductive structural material as needed and so as to give the final structure (after release from the sacrificial material) a desired configuration of conductive and dielectric structural materials.

FIG. 15 presents a block diagram of a process according to an ninth group of embodiments of the present invention where a grid of dielectric structural material and sacrificial conductive material is formed so as to allow deposition of conductive structural material as needed and so as to give the final structure (after release from the sacrificial material) a desired configuration of conductive and dielectric structural materials where the conductive structural material is deposited first, the conductive sacrificial material deposited second, and then the dielectric material.

FIGS. 16A-16D schematically present side views of a sample structure which illustrate selected states of a process for electrochemically fabricating a structure on a dielectric substrate according to an embodiment of the invention.

FIGS. 17A-17V schematically depict side views and top views illustrating various states of a process for forming a multilayer structure on a dielectric substrate according to an eleventh embodiment of the invention where the process produces a contact or bonding pad formed out of a transition layer material that was initially part of a seed layer formed on the substrate.

FIGS. 18A-18H schematically depict side views of various states of the process of a twelfth embodiment of the invention as applied to the formation of a particular structure wherein an integrated circuit is incorporated into the formation of an electrochemically fabricated conductive and dielectric structure.

### DETAILED DESCRIPTION OF PREFERRED EMBODIMENTS OF THE INVENTION

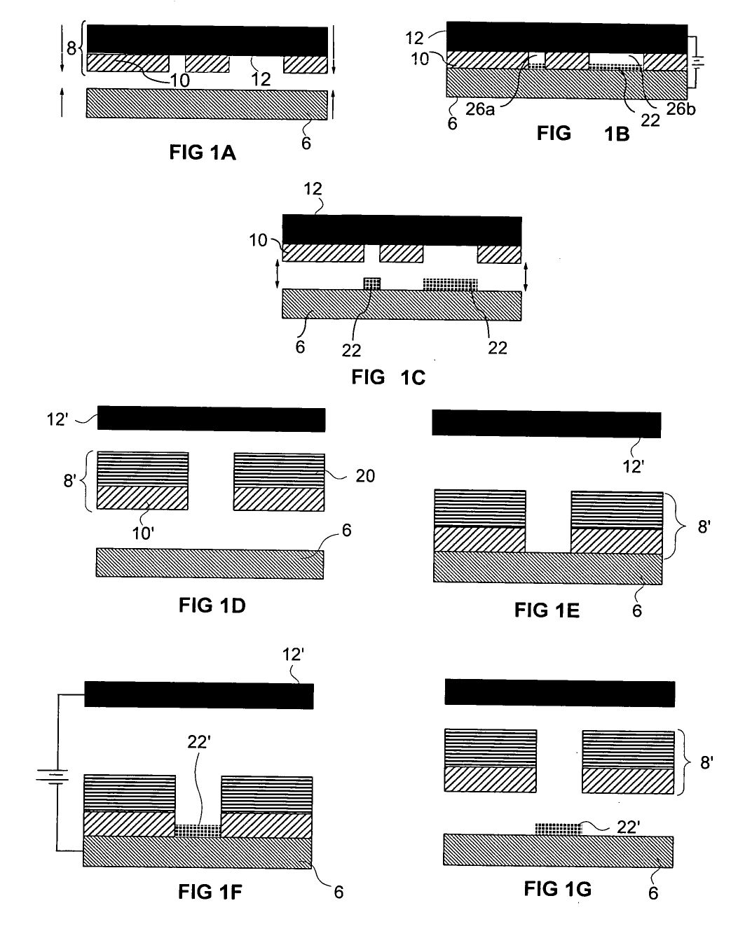

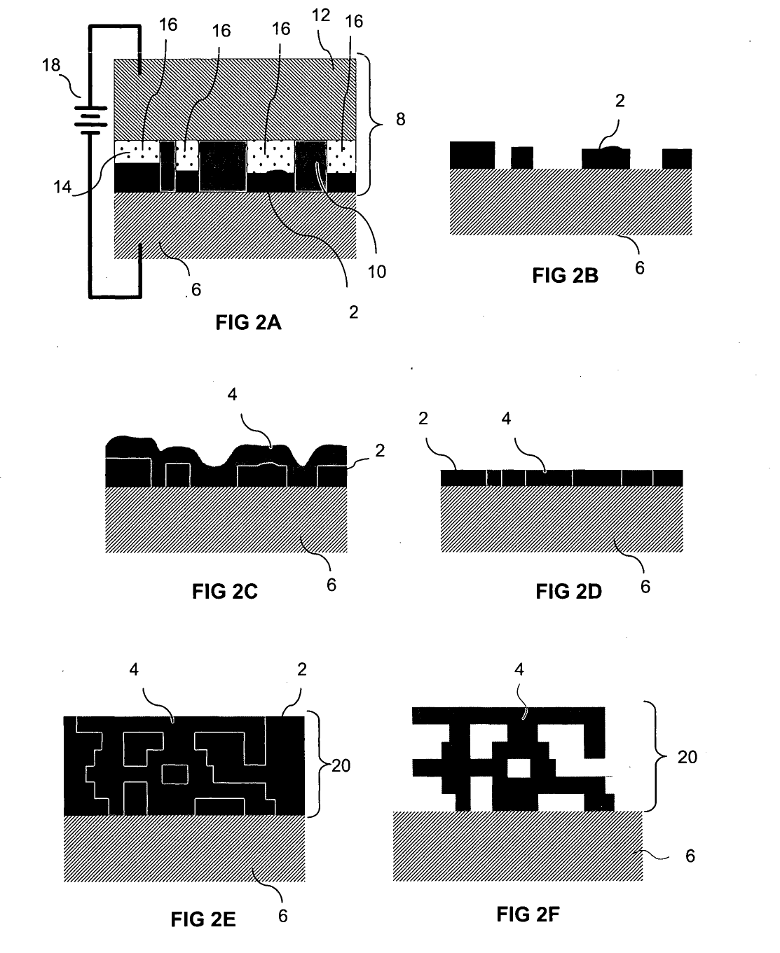

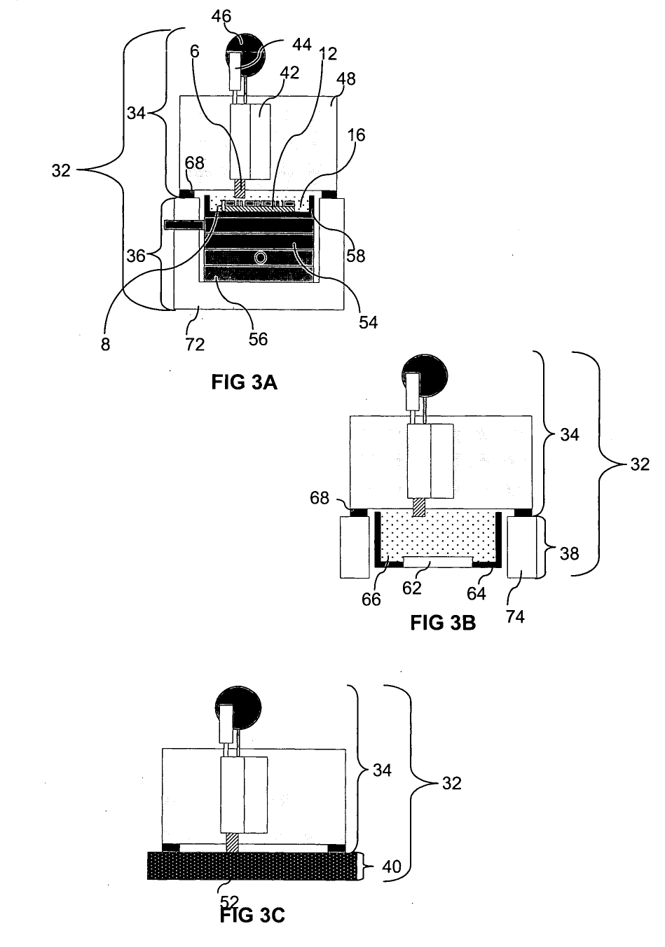

FIGS. 1A-1G, 2A-2F, and 3A-3C illustrate various features of one form of electrochemical fabrication that are known. Other electrochemical fabrication techniques are set forth In the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

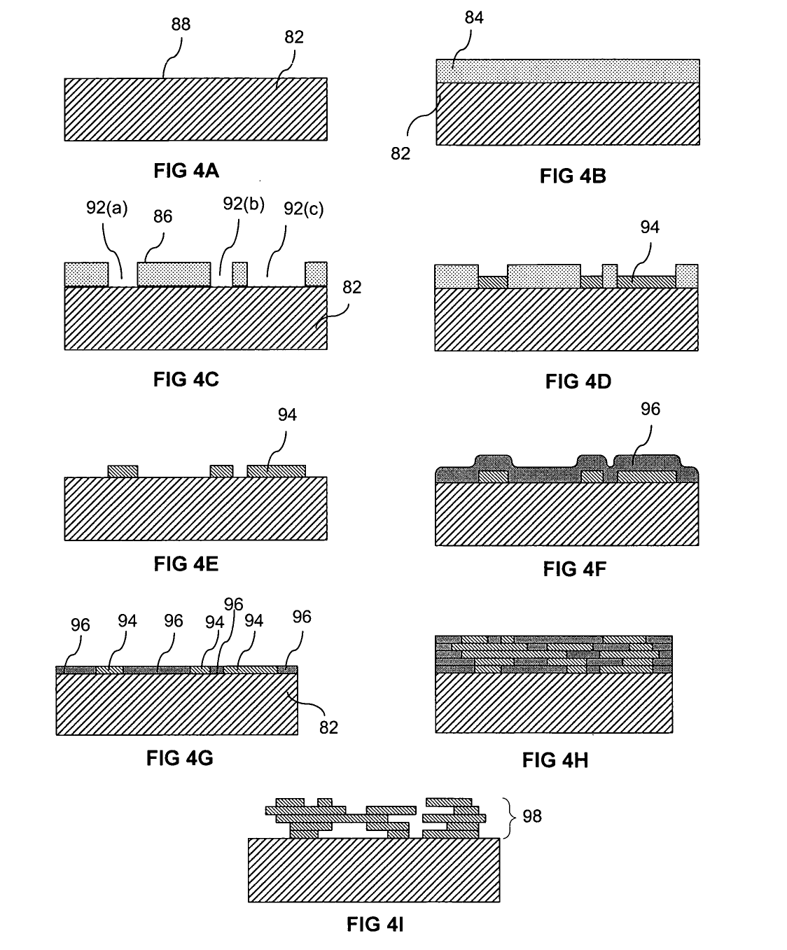

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 41 to yield a desired 3-D structure 98 (e.g. component or device).

The various embodiments, alternatives, and techniques disclosed herein may form multi-layer structures using a single patterning technique on all layers or using different patterning techniques on different layers. For example, different types of patterning masks and masking techniques may be used or even techniques that perform direct selective depositions without the need for masking may be used. For example, the methods disclosed herein for incorporating dielectrics may be used in combination with conformable contact masks and/or non-conformable contact masks and masking operations on all, some, or even no layers. Proximity masks and masking operations (i.e. operations that use masks that at least partially selectively shield a substrate by their proximity to the substrate even if contact is not made) may be used and/or adhered masks and masking operations (masks and operations that use masks that are adhered to a substrate onto which selective deposition or etching is to occur as opposed to only being contacted to it) may be used.

FIG. 5 provides a block diagram of some basic operations that form part of a first group of embodiments of the invention.

The process of FIG. 5 begins with block 102 which calls for the obtaining of a patterned deposit of at least one first material, for example, a dielectric (or a precursor thereto) or a conductive material. The operation of block 102 may actually be a plurality of operations. For example, the patterned deposit may actually be formed from multiple deposited materials or might actually be multiple patterns of different deposited materials. As another example, the patterned deposit might result from the blanket deposition of a first material followed by the selective etching of a pattern into the first material. In such embodiments the blanket deposition and the selective etching may be separated by a planarization operation. The deposited material may be a conductive material of the structural type or of the sacrificial type. The deposited material may be a dielectric material or a conductive material that may be converted to a dielectric material.

From block 102 the process moves forward to block 104. Block 104 calls for the deposition of at least one second material which may again be of the conductive type or of the dielectric type. The second material may be deposited in a blanket manner or may be deposited in a selective manner.

Next the process moves forward to block 106 which calls for the optional planarization of the deposited materials. This planarization may occur in a variety of ways, for example, by lapping, by chemical mechanical planarization, and/or by a machining operation.

From block 106 the process moves forward to block 108 which calls for the repetition of operations 1 to 3 of blocks 102, 104 and 106 respectively. Blocks 102 and 104 may in addition to the depositing of material also involve the processing of the deposited materials to achieve desired properties. Such processing may involve the heat treatment of the deposited materials, chemical treatment of the deposited materials, back filling of the deposited materials with supplemental material, and the like.

From block 108 the process moves forward to block 110 which calls for the performance of any additional operations that are necessary to give the deposited layers desired attributes. Such processing may involve those noted above for operations 102-104.

From operation 110 the process moves forward to operation 112 which calls for the optional repeating of operations 1 thru 5 one or more times to increase the number of layers that form the multi layer structure. In other words the operations of block 110 and 112 together imply that attribute enhancing operations may not only occur at the completion of the layer formation process but may also occur after only partial formation of the plurality of layers making up the multilayer structure.

From block 112 the process moves forward to block 114 which calls for the performance of any additional post processing operations that are necessary. Such post processing operations may include removal of one or more of the first or second materials. Such post processing may additionally or alternatively include the separation of the formed multi-layer structure from the substrate on which it was produced.

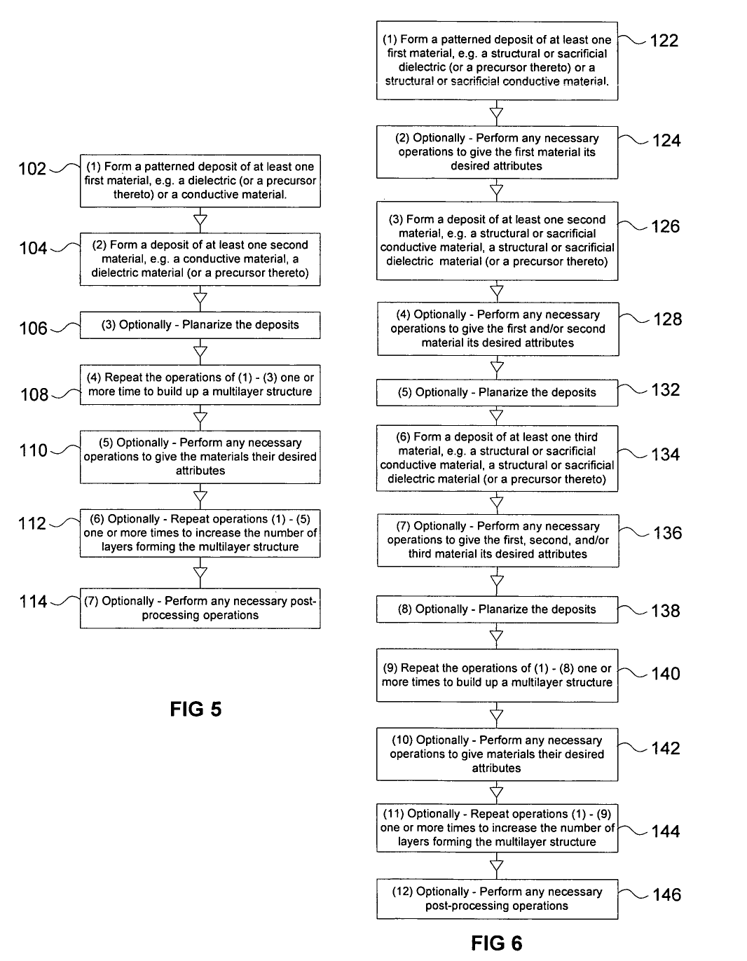

FIG. 6 provides a block diagram of some basic operations that form part of a second group of embodiments of the invention.

The process of FIG. 6 begins with block 122 which calls for the obtaining of a patterned deposit of at least one first material where the patterned deposit may be of a structural dielectric material, a sacrificial dielectric material, a structural conductive material or a sacrificial conductive material.

From block 122 the process moves forward to block 124 which calls for the optional performance of any necessary operations to give the deposited materials their desired attributes. Such operations may be similar to those described previously in association with FIG. 5.

Next the process moves forward to block 126 which calls for the obtaining of a deposit of at least one second material, where the second material is one of a sacrificial conductive material, a structural conductive material, a sacrificial dielectric material or a structural dielectric material. In many embodiments the second material is of a different type than the first material. From block 126 the process moves forward to block 128 which like block 124 calls for the optional performance of any necessary operations required to give the materials their desired attributes.

From block 128 the process moves forward to block 132 which calls for the optional planarization of the deposited materials. It should be understood that in some alternative embodiments the order of the optional operations of block 128 and 132 may be reversed and/or the optional operation of block 132 may occur both before and after the operations of block 128.

From block 132 the process moves forward to block 134 which calls for the deposition of at least one third material. In many embodiments the third material is of a different type then the first material or the second material. In such embodiments, for example, a structural dielectric material may be one of the first through third materials deposited, a structural conductive material may be another of the first through third materials deposited while a sacrificial conductive material may be another of the first though third materials deposited.

After block 134 the process moves forward to block 136 which calls for the optional performance of any necessary operations to give the materials their desired attributes in a manner analogous to that of blocks 124 and 128.

From block 136 the process moves forward to block 138 which calls for the optional planarization of the deposited materials. Like blocks 132 and 128 the order of operations called for by blocks 136 and 138 may be reversed or alternately repeated more then one time.

From block 138 the process moves forward to block 140 which calls for the repeated operations of blocks 1 through 8 one ore more times to build up a multi-layer structure. After which the process moves forward to block 142 which calls for the optional performance of any necessary operations to give the deposited materials their desired attributes.

After block 142 the process moves forward to block 144 which calls for the repetition of blocks 1-9 one ore more times to increase the number of layers that form the multi-layer structure.

From block 144 the process moves forward to block 146 which calls for the performance of any post processing operations that are necessary to complete formation of the multi-layer structure.

In some embodiments of the invention, electrophoretic processes may be used in the deposition of dielectric materials (e.g. microscale and nanoscale materials) and even in the deposition of conductive materials. In still other embodiments of the invention other processes may be used to deposit dielectric materials, for example, dielectric materials may deposited by spreading or flowing a curable material over a surface to receive the dielectric material. The surface may be of a patterned type with voids to receive the dielectric or it may be unpatterned where it is intended that the deposited material blanket coat the substrate (or previous layer of the structure). The coating material may then be caused to solidify, or allowed to solidify, in a blanket manner or in a patterned manner (e.g. by selective or blanket exposure to curing radiation or by exposure to heat, vacuum or simply time, to allow a solvent or the like to evaporate. The dielectric material so formed may be patterned in a desired configuration or it may undergo additional patterning operations. FIGS. 8-10 provide block diagrams based on the process of FIG. 6 which alternative approaches to the use of electrophoretic depositions to deposit a dielectric material. In some embodiments, the dielectric material may take the form of a liquid or dry film photoresist.

The selective electrophoretic deposition of a material may involve contact, proximity, and/or adhered masks and masking operations. Electrophoretic coating involves suspended, charged particles that migrate under an electric field to an electrode to form a coating. A large variety of materials can be deposited this way including ceramics, polymers, phosphors, glass, and even metals. Deposition rates may be orders of magnitude higher than that for electroplating (e.g., ˜1 mm/min).

A first embodiment of the invention, based on the process of FIG. 5, deposits a conductive material and another material that is conductive at the time of deposition but is made to become insulative (or dielectric) after deposition (i.e. the deposition involves a precursor to what will be a dielectric material). If the requirements for dielectric material are not stringent (i.e., in terms of dielectric constant), it may be possible to deposit a photoconductive material while the material is being illuminated. After formation of the fabricated device, the device or at least those portions of the device formed from the photoconductive material may be sealed to prevent illumination thus achieving the desired dielectric attributes. One example of such a photoconductor is amorphous silicon. Such a photoconductor may be electrophoretically deposited.

A second embodiment of the invention, based on the process of FIG. 5, deposits a conductive material (e.g. by electroplating) and electrophoretically deposits insulating particles which are coated with a thin conductive film (e.g., a metal), such that the particles and the deposit is initially conductive due to intimate contact between the metal surfaces of each particle. After formation, the conductive paths connecting the surfaces of the particles together are broken to yield an insulative material. For example, the deposit can be heated to cause melting of the conductive surface films. The melted material may then form isolated pockets of conductive material, as a result of surface tension and de-wetting effects. Alternatively, a flow of hot gas or non-conductive, potentially solidifiable, liquid may be used to force out the conductive material and even to replace it with a dielectric material. Alternatively, the structure may be subjected to an etchant that attacks the conductive material of the film without significantly damaging any structural materials present. In this way the conductive film material may be removed, leaving just the insulating particles. In some embodiments, the conductive material coating the electrophoretic deposited particles may be a sacrificial metal wherein the layer-by-layer electrophoretic deposition of material also calls for the layer-by-layer deposition (e.g. via electroplating) of sacrificial metal to fill the voids between the powder particles or at least those voids near the surface of the deposited particles.

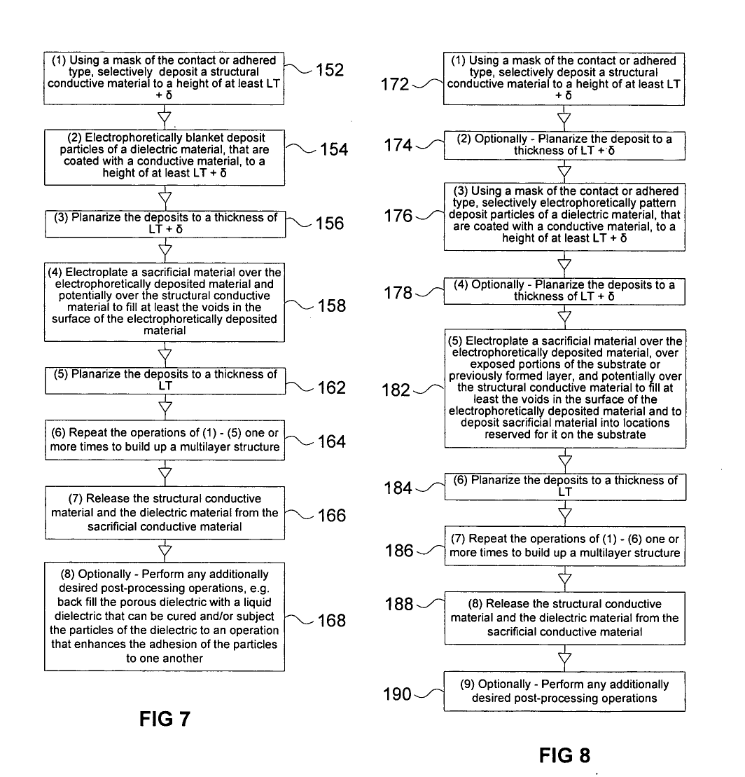

FIG. 7 provides a block diagram of a process according to a third group of embodiments, which are based on the general process of FIG. 5, where a conductive structural material is deposited followed by electrophoretic deposition of a conductively coated dielectric material and then by a deposition of a sacrificial conductive material (to fill voids or pores within the electrophoretically deposited material).

The process of FIG. 7 begins with block 152 which calls for the use of a contact or adhered mask in the selective deposition of a structural conductive material where the height of deposition is at least LT plus an incremental amount δ.

From block 152 the process moves forward to block 154 which calls for electrophoretic blanket deposition of a dielectric material which has individual particles coated with a conductive material and wherein the height of deposition is at least equal to the layer thickness LT+δ.

From block 154 the process moves forward to block 156 which calls for the planarization of the deposits to a thickness of LT+δ.

Next the process moves forward to block 158 which calls for the electroplating of a conductive sacrificial material over the electrophoretically deposited material to fill in at least the voids located near the surface of the electrophoretically deposited material.

Next the process moves forward to block 162 which calls for the planarization of the deposits to a thickness equal to that of LT. From block 162 the process moves forward to block 164 which calls for the repetition of operations 1-5 of blocks 152-162 respectively so that a multi-layer structure is formed.

Next the process moves forward to block 166 which calls for the release of the structural conductive material and the dielectric material from the sacrificial conductive material which is located within the voids of the dielectric material (the electrophoretically deposited material).

Next the process moves forward to block 168 which optionally calls for the performance of any additionally desired post processing operations. For example, such operations may include the back filling of the porous dielectric material with a liquid dielectric that can be cured. Another such post processing operation might include the subjection of the particles of the dielectric to an operation that enhances the adhesion of the particles to one another.

FIG. 8 provides a block diagram of a process according to a fourth group of embodiments, which are based on the general process of FIG. 6, where a conductive structural material is deposited, an electrophoretic deposition of material occurs and a sacrificial conductive material is deposited to fill the voids in the electrophoretically deposited material and to fill regions over the substrate where only the sacrificial conductive material is to be located.

The Process of FIG. 8 begins with block 172 which calls for the use of a contact or adhered mask in the selective deposition of a structural conductive material where the height of deposition should be at least the layer thickness LT plus an incremental amount δ.

After the deposition of block 172 the process optionally moves forward to block 174 which calls for the planarization of the deposit to a thickness of LT+δ.

Next the process moves forward to the selective electrophoretic deposition of particles of a dielectric material that are coated with a conductive material. The selective deposition occurs via a contact or adhered type mask and the height of deposition is preferably at least LT+δ.

Next the process moves forward to block 178 which optionally calls for the planarization of the deposits to a thickness of LT+δ. In alternative embodiments that include both a planarization operation 174 and a planarization operation 178 the planarization operation 174 may be at a height some what greater then LT+6 and the associated deposition of block 172 may have a somewhat thicker minimum height.

From block 178 the process moves forward to block 172 which calls for the electroplating of a sacrificial material over both the electrophoretically deposited material and over exposed portions of the substrate (or previously formed layer). The sacrificial material may also be deposited over the structural conductive material deposited in association with block 172.

After completion of the operations of block 182 the process moves forward to block 184 which calls for the polarization of the deposits to a thickness equal to the layer thickness LT.

Next the process moves forward to block 186 which calls for the repetition of operations 1 through 6 associated with blocks 172-184 respectively, one or more times to build up a multi-layer structure. It will be understood that in alternative embodiments to this embodiment as well as to the other embodiments disclosed in this application instead of a repetition of operations used to form one layer of the structure, alternative formation operations may be used to form other layers of the structure.

From block 186 the process moves forward to block 188 which calls for the release of the structural conductive material and the dielectric material from the sacrificial conductive material.

Next the process moves forward to block 180 which calls optionally for the performance of any additionally desired post processing operations. It will be understood by those of skill in the art that in alternative embodiments the order of operations of block 188 and 190 may be reversed.

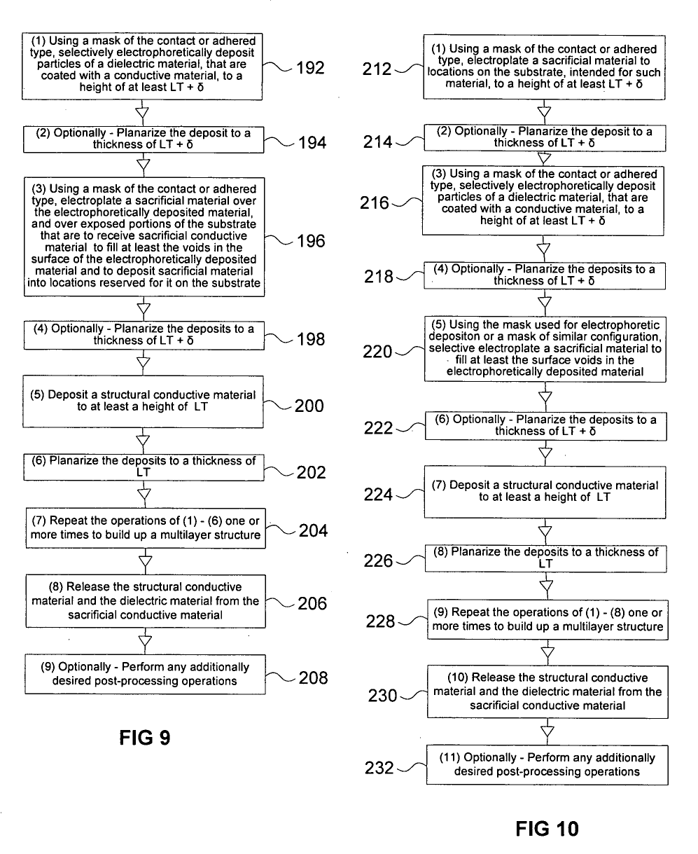

FIG. 9 provides a block diagram of a process according to a fifth group of embodiments, which are based on the general process of FIG. 6, where an electrophoretic selective deposition of a material occurs, followed by deposition of a sacrificial conductive material to fill voids or pores within the electrophoretically deposited material and to fill regions over the substrate where only the sacrificial conductive material is to be located, and followed by deposition of a conductive structural material.

The process of FIG. 9 begins with block 192 which calls for the use of a mask of the contact or adhered type in the selective electrophoretic deposition of particles of a dielectric material that are coated with a conductive material. The height of deposition is preferably equal to or greater than the layer thickness LT plus an incremental amount δ.

From block 192 the process moves forward to block 194 which optionally calls for the planarization of the material deposited in association with block 192.

From block 194 the process moves forward to block 196 which calls for the use of a mask of the contact or adhered type in the electroplating of a conductive sacrificial material over the electrophoretically deposited material and over the exposed portions of the substrate or previously formed layer that are to receive the sacrificial conductive material.

From block 196 the process moves forward to block 198 which optionally calls for the planarization of deposits to a thickness equal to or greater than the layer thickness LT plus an incremental amount δ. It will be understood by those of skill in the art that in alternative embodiments where a planarization operation of block 198 and a planarization operation of block 194 are to be performed, it may be desirable to perform the planarization operation of block 194 at a height somewhat above that of height of planarization of block 198. Similarly the height of deposition associated with block 192 may be set at a minimum that is greater than LT+δ.

From block 198 the process moves forward to block 200 which calls for the deposition of a conductive structural material having a height at least as great as LT. After the deposition of block 200 the process moves forward to block 202 which calls for the planarization of the deposit to a height of LT. The processes of blocks 204, 206 and 208 are similar to those called for by blocks 186, 188 and 190 respectively of FIG. 8.

FIG. 10 provides a block diagram of a process according to a sixth group of embodiments, which are based on the general process of FIG. 6, where a sacrificial conductive material is selectively deposited, a selective electrophoretic deposition of a conductively coated dielectric material occurs, a second selective deposition of sacrificial material occurs, and then a deposition of a conductive structural material occurs.

The process of FIG. 10 begins with block 212 which calls for the selective electroplating of a sacrificial material to locations on the substrate or previously formed layer intended for receiving such material. The height of deposition is preferably at least LT+6, and the selective deposition preferably occurs via use of a mask of the contact or adhered type. It will be understood by those of skill in the art that alternatives to this embodiment as well as to the other embodiments disclosed herein may make use of other techniques for selectively depositing conductive, sacrificial and structural materials (e.g. electroless deposition).

From block 212 the process moves forward to block 214 which calls for the optional planarization of the deposit made in association with block 212. From block 214 the process moves forward to block 216 which calls for selective electrophoretic deposition of particles of a dielectric material that are coated with a conductive material. The height of deposition is preferably at least equal to the layer thickness plus an incremental amount δ.

From block 216 the process moves forward to block 218 which calls for the optional planarization of the deposits to a thickness of LT+δ. As noted previously if the optional planarization processes of block 214 and 218 are both to be used the planarization height associated with block 214 may be somewhat greater than the amount LT+6 indicated in the figure.

From block 218 the process moves forward to block 220 which calls for the electroplating of a sacrificial material to fill at least the surface of the voids (i.e. pores) in the electrophoretically deposited material. The mask used for the selective deposition of block 220 may be the same mask used for the electrophoretic deposition of block 216 or alternatively it may be a different mask.

From block 220 the process moves forward to block 222 which optionally calls for the planarization of the deposits to a thickness of the LT+δ. It will be understood by those of skill in the art that in alternative embodiments where the planarization of block 222 is to be used along with one or both of the planarization operations of block 214 and 218 it may be desirable to set the level of planarization in block 218 and/or in block 214 to a height greater then LT+δ.

From block 222 the process moves forward to block 224 which calls for the deposition of a conductive structural material to a height of at least LT.

Block 226 then calls for the planarization of the deposited material to a thickness of the layer thickness, LT. The operations of blocks 228, 230 and 232 are analogous to those of blocks 186, 188 and 190 respectively.

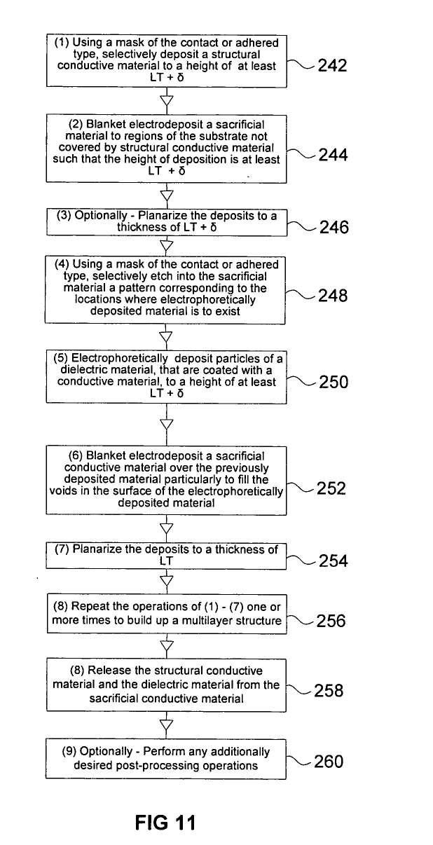

FIG. 11 provides a block diagram of a process according to a seventh group of embodiments, which are based on the general process of FIG. 6, where a conductive structural material is selectively deposited, a blanket deposition of conductive sacrificial material occurs, an etching operation creates voids in the sacrificial material where a dielectric material is to be located, a blanket electrophoretic deposition of a conductively coated dielectric material occurs, and finally a second selective deposition of sacrificial material occurs.

The process of FIG. 11 begins with block 242 which calls for the selective deposition of a conductive structural material where the deposition height is preferably at least as great as the layer thickness plus an incremental amount (LT+δ). The deposition is performed using a contact or adhered mask. From block 242 the process moves forward to block 244 which calls for the blanket deposition of a sacrificial material to all regions of a substrate not covered by the structural conductive material deposited in association with block 242. The height of deposition is preferably at least equal to LT +δ.

From block 244 the process moves forward to block 246 which calls for the optional planarization of the deposits to a height equal to LT+δ.

From block 246 the process moves forward to block 248 which calls for the selective etching into the sacrificial material using a mask of the contact or adhered type such that a pattern corresponding to the locations where an electrophoretically deposited material is to exist.

From block 248 the process moves forward to block 250 which calls for the electrophoretic deposition of a dielectric material which includes particles that are covered with a conductive material. The height of deposition is preferably no less than LT+6.

From block 250 the process moves forward to block 252 which calls for the blanket electrodeposition of a conductive sacrificial material over the previously deposited materials and particularly for the purpose of filling in the voids in the surface of the electrophoretically deposited material.

From block 252 the process moves forward to block 254 which calls for the planarization of the deposits to a thickness equal to LT. The operations of block 256, 258 and 260 are analogous to those of blocks 186, 188 and 190 respectively of FIG. 8.

Those of skill in the art will understand that various embodiments, others than those of FIGS. 7-11, are possible for building with a conductive structural material and an electrophoretically deposited material. Other material deposition orders are possible and other material deposition techniques are possible. Those of skill in the art will understand that the build processes of FIGS. 7-11 will have application to other building processes where other material deposition operations are used.

In some embodiments, insulating particles may remain non-bonded while in other embodiments they may be bonded together. In some embodiments, air or gas pockets may remain between individual particles while in other embodiments, those pockets may be decreased in size or even eliminated by either compaction of the powder particles or by backfilling into the voids with a secondary solidifiable, non-conductive material. Such binding and/or compaction or densification may occur by application of heat, application of pressure, and/or a combination of heat and pressure to melt and bind or to sinter the particles together. In other embodiments back filling with a flowable fluid-like material may occur to cause binding or densification. For example, a reactive gas may be flow through the particles to initiate a chemical reaction that causes binding. A flowable liquid may be injected or otherwise made to fill, or at least partially occupy, the voids in between the particles after which the flowable liquid may be made to solidify by cooling (i.e. transition from a melted state to a solid state) by heating (e.g. to initiate a thermal polymerization process or to cause evaporation of a solvent), by exposure to selected radiation to cause a selective chemical reaction (e.g. polymerization), or the like. The operations that bind the particles together may occur on a layer-by-layer basis, after formation of a number of layers, or as a post processing operation.

In some other embodiments of the present invention, a lattice of conductive sacrificial material and dielectric structural material is formed along with conductive elements of the structure. The conductive material of the lattice is formed to avoid need for a seed layer over regions of dielectric material. The spacing of the sacrificial conductive elements are such that relative small gaps of dielectric material exist which can be readily bridged by a mushrooming of depositions (i.e. a spreading of the depositions over non-conductive material in the plane of the substrate as deposition height grows). The lattice preferably, provides a connection between all of the conductive sacrificial elements all the sacrificial material may be accessed and removed after the structure is formed and so that conductive paths exist so that each conductive element found on a layer may act as an initiation point for electrodeposition operations and for the spreading out of the depositions. Of course in alternative embodiments it may not be necessary for all sacrificial material to be interconnected in this manner.

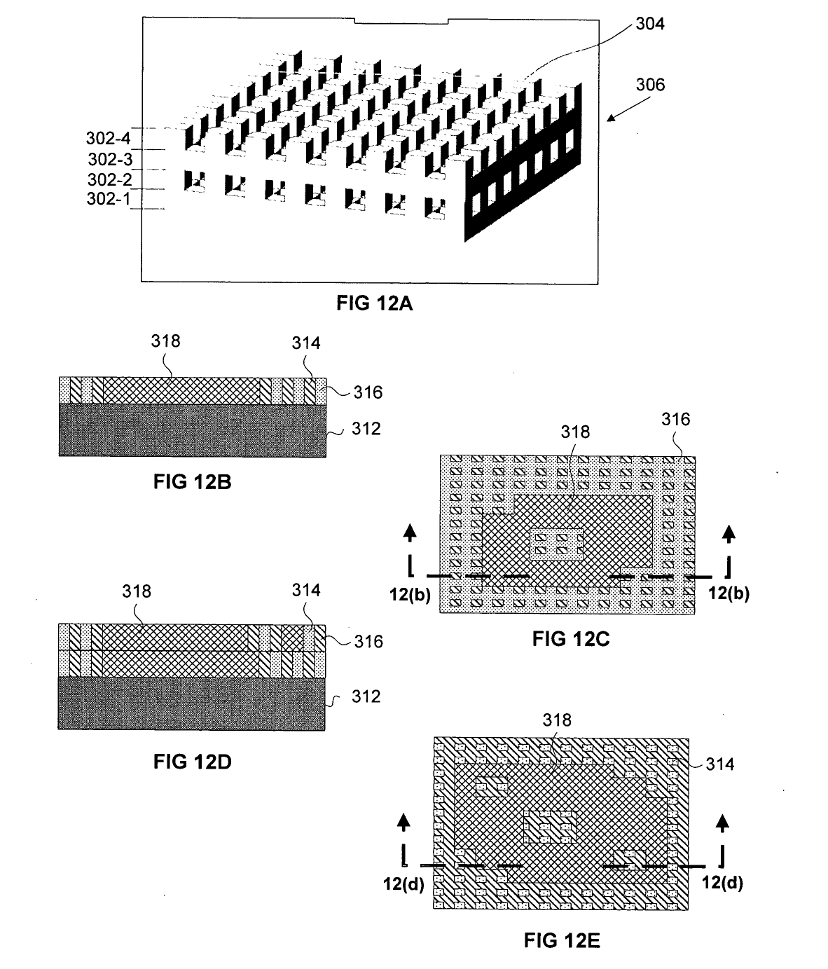

Such structures may, for example, take the form of that shown in FIG. 12A. For simplicity only one of the material grids 306 (either the conductive sacrificial material or the dielectric material) is shown in the figure. The other material grid would take on a complementary form to that of grid 306. Four layers 302-1 to 302-4 of grid 306 is shown and for simplicity no structural conductive material is shown on any of the layers. The girds may be based on the cubes shown or on any other geometric structures that offer small gaps of dielectric material between regions of conductive sacrificial material and that offer conductive sacrificial material in patterns that leave all required regions supported by the dielectric material and that provide sufficient larger flow paths for removing the sacrificial conductive material when the structure is completed. In some alternative embodiments, the conductive sacrificial material may not need to exist in a tight grid on all layers but instead need only exist to such an extent that conductive structural material may be deposited in required locations. In still other alternative embodiments, the formation of a conductive grid may be aborted or reinitiated by use of a seed layer when it is required or anticipated to be required within a certain number of layers. In some alternative embodiments, the pattern of the grid need not alternate or otherwise change configuration each layer but instead may remain unchanged for a plurality of layer, for example, to increase the size of flow paths for eventual removal of the sacrificial conductive material.

After all layers are deposited, the sacrificial metal lattice may be etched to remove the metal lattice, leaving the dielectric lattice filled with air (e.g., for a low-K application). Or, if desired, the lattice can be infiltrated with the same or a different dielectric.

FIGS. 12B and 12D provide schematic side views of cuts through a first and second layer showing a substrate 312, portions of the layer where conductive structural material 318 is located, where conductive sacrificial material 314 is located, and where the dielectric grid of structural material 316 is located. FIGS. 12C and 12E show tops views of the layers of FIGS. 12B and 12D respectively along with cut lines 12B-12B and 12D-12D shown where the vertical slices of FIGS. 12B and 12D were taken.

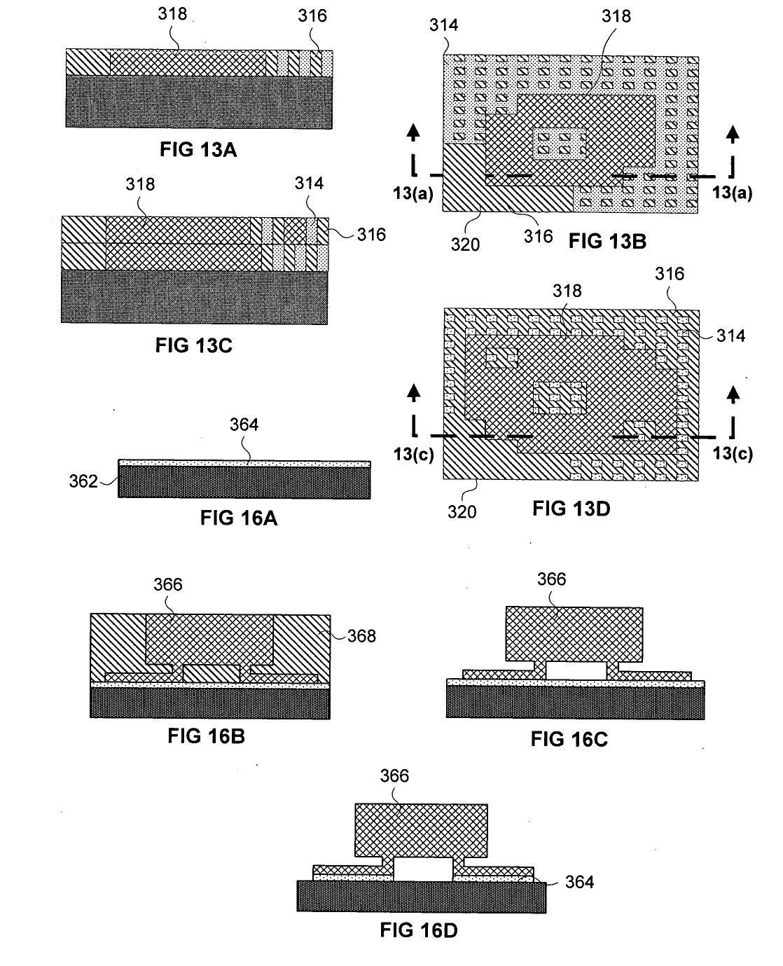

In some lattice based embodiments, the lattice need not take on a rectangular box-like structure as shown in FIGS. 12A-12E, instead the dielectric material may be located in certain regions only while other portions of a build volume (e.g. a rectangular region defining each of a plurality of potential layers areas) may be filled with only conductive sacrificial material so that when etching occurs all material may be removed from those other portions so that what remains is a structure of desired configuration of conductive material and of a desired configuration of a dielectric material. This is illustrated in FIGS. 13A-13D where a portion 320 of the grid structure has been modified so that only conductive sacrificial material 314 exists in the lower left of each of the two cross-sections. FIGS. 13A-13D correspond to FIGS. 12B-12E with the exception of the redefined regions to be occupied only by conductive sacrificial material.

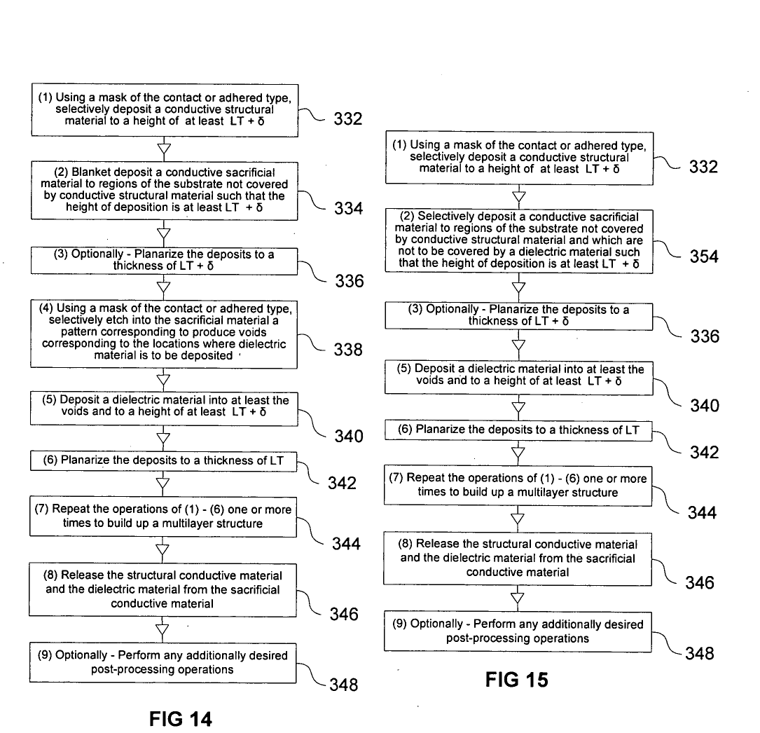

FIG. 14 presents a block diagram of a process according to an eighth group of embodiments of the present invention where a grid of dielectric structural material and sacrificial conductive material is formed so as to allow deposition of conductive structural material as needed and so as to give the final structure (after release from the sacrificial material) a desired configuration of conductive and dielectric structural materials where the conductive structural material is deposited first, the conductive sacrificial material deposited second and then etched into to make voids for accepting dielectric material.

The process of FIG. 14 begins with block 332 which calls for the use of a contact or adhered type mask for selectively depositing a conductive structural material onto the substrate or previously formed layer. The height of deposition is preferably at least the layer thickness plus an incremental amount (LT+δ).

From block 332 the process moves forward to block 334 which calls for the blanket deposition of a conductive sacrificial material to regions of the substrate or previously formed layer not covered by the conductive structural material laid down during operation 332. The height of deposition is preferably at least equal to LT+δ.

From block 334 the process moves forward to block 336 which calls for the optional planarization of the deposits to a thickness of LT+δ.

From block 336 the process moves forward to block 338 which calls for the using of a mask of either the contact or adhered type for the selective etching into the sacrificial conductive material so as to form a pattern of voids corresponding to the locations where dielectric material is to be located.

After operation 338 is completed the process moves forward to block 340 which calls for the deposition of the dielectric material into at least the voids formed in the sacrificial material and to a height of at least the layer thickness plus an incremental amount. The deposition of dielectric material into the voids may also result in the deposition of dielectric material above the previously deposited materials. The deposition of the dielectric material may occur in a number of different ways. For example, the deposition may occur by electrophoretic means. As another example it may occur by dipping the structure into a desired liquid dielectric so as to overfill the voids and then spinning or wiping excess liquid from the surface of the structure and thereafter wiping or spinning the excess material away. Alternatively the liquid dielectric may be applied and hardened without removing any excess material and allowing a subsequent planarization operation to remove the excess material.

In still other alternatives the dielectric material may be applied by spraying, by sputtering, by stamping, and/or by ink jet dispensing. The deposited dielectric material may, for example, be of a ceramic type, thermal polymer type, thermoset polymer type, or photocurable polymer type. Still other types of dielectrics and deposition techniques will be understood by those of skill in the art upon review of the teachings herein.

After completion of the operation of block 340 the process moves forward to block 342 which calls for the planarization of the deposited materials to a thickness equal to that of the layer thickness. The repeating, releasing and optional post processing operations of blocks 344, 346 and 348 are similar to those discussed herein previously with regard to blocks 186, 188 and 190 of FIG. 8 and as such will not be discussed further at this time.

FIG. 15 presents a block diagram of a process according to an ninth group of embodiments of the present invention where a grid of dielectric structural material and sacrificial conductive material is formed so as to allow deposition of conductive structural material as needed and so as to give the final structure (after release from the sacrificial material) a desired configuration of conductive and dielectric structural materials where the conductive structural material is deposited first, the conductive sacrificial material deposited second, and then the dielectric material.

The process of FIG. 15 is similar to that of FIG. 14 and like operation blocks are labeled with similar reference numerals. The process of FIG. 25 begins with block 332 and the deposition of a conductive structural material in a manner similar to that called for in FIG. 14.

Next the process of FIG. 15 moves forward to block 354 which calls for the selective deposition of a conductive sacrificial material to regions of the substrate not covered by the conductive structural material and which are not to be covered by a dielectric material. The deposition of block 354 leaves voids over the substrate or previously formed layer where dielectric material is to be deposited.

After the deposition of block 354 the process continues through blocks 336, 340, 342, 344, 346 and 348 in the same manner as was previously described with regard to FIG. 14. As such these blocks and associated operations will not be described further herein at this time. It should be noted that in the various embodiments discussed up to this point some optional planarization operations have been called for where deposits have not completely filled in regions over the substrate or previously formed layer. Such planarization operations may be formed with such voids in the deposits after which a clean up operation such as a spraying operation or vacuum extraction operation may be used to remove any planarization debris from within the voids.

In alternative embodiments the voids may be filled in with a temporary material so that planarization may occur with reduced risk of edge damage to portions of the deposited materials. Where, after the planarization operation is completed, the temporary material would be removed in any appropriate manner (e.g. by selective etching, development, melting, ablation with or without assistance of vacuum techniques or spraying or the like).

Those of skill in the art will understand that, modified embodiments for working with dielectric and sacrificial material grids are possible. It will be understood that different orders of deposition are possible, other orders of etching and filling are possible, working with additional materials of the conductive sacrificial or structural types are possible and working with dielectric sacrificial materials and/or additional dielectric structural materials is possible.

FIGS. 16A-16D schematically present side views of a sample structure which illustrate selected states of a process for electrochemically fabricating a structure on a dielectric substrate according to a tenth embodiment of the invention. In FIG. 16A, a dielectric 362 is shown as having been metallized with a thin film or seed layer 364, e.g., a layer of Au over Cr, Au over Ti, Au over W, Au over Ti/W. In FIG. 16B, a structure 366 is shown as having been formed and the structure is shown as still being embedded in a sacrificial material 368. In FIG. 16C, the sacrificial material 368 is shown as having been removed (e.g. by etching). In FIG. 16D, the metal film 364 is shown as having been removed in exposed regions. The removal of the film may occur in a one or two step etching process, e.g. one to remove the upper most portion (i.e. initially exposed portion—e.g. Au) and a second etch to remove any adhesion layer material (e.g. Cr, Ti, W, or Ti/W). This etching is preferably performed using a dilute etching for a controlled period of time so that all of the exposed material is removed without causing excess under cutting below the structural material located on the seed layer. This controlled etch is usually considered a quick etch. The result of the process is a selected pattern of structural material bonded to a dielectric via a selective pattern of a seed layer material. This process may be summarized as including the following operations: (1) blanket deposition of a seed layer material, (2) electrochemical fabrication of a plurality of layers forming a desired three-dimensional structure from a structural material and from a sacrificial material, (3) removal of the sacrificial material; and (4) a controlled removal of exposed portions of the seed layer material to leave isolated regions of conductive material on the substrate.

An eleventh embodiment of the invention provides a method for forming a multilayer structure on a dielectric substrate wherein the structure once formed will include a contact or bonding pad formed from a material forming a transition layer of a seed layer initially applied to the substrate. The process forms a multilayer structure on a dielectric substrate using a conductive structural material, a conductive sacrificial material, use of a first seed layer material combination, and use of a second seed layer material combination. The process includes the following operations:
(1) Provide a dielectric substrate on which layers of a structure are to be formed,
(2) Deposit a seed layer on to the substrate, including:
   (a) Depositing a thin coating of an adhesion layer material (e.g. by sputtering titanium (Ti) to a thickness of about 100-1000 angstroms and more preferably between about 300-700 angstroms in thickness)
   (b) Deposit a thin layer of a transition material (e.g. gold (Au) having a thickness of about 0.1-1.0 microns and more preferably between about 0.1 and 0.5 microns). The transition layer is preferably a material onto which electroplating may be readily performed and which will not be attacked during a subsequent removal (e.g. etching) of the sacrificial material.
(3) Apply and pattern a masking material to form voids therein in locations where a structural conductive material is intended to be deposited and adhere to the substrate (i.e. to the seed layer on the substrate). This operation may involve the use of a photoresist that is applied, patterned, and then developed.
(4) Deposit the conductive structural material into the voids in the masking material (e.g. electroplate nickel).
(5) Pattern the masking material further, or remove the masking material and redeposit and pattern fresh masking material, so that masking material remains only over those portions of the seed layer material that are uncovered by structural conductive material but are to remain as part of the final structure.
(6) Etch away the exposed transition layer material in a controlled manner so that little or no damage is done to the portion of the transition layer that is located under the masking material and under the conductive structural material.
(7) Etch away the exposed adhesion layer material in a controlled manner so that little or no damage is done to the portion of the adhesion layer that is located under the masking material and under the conductive structural material leaving portions of the dielectric substrate exposed.
(8) Remove the masking material (e.g. strip the photoresist material). In some alternative embodiments, the orders of operations (7) and (8) may be reversed.
(9) Blanket deposit an adhesion layer (e.g. by sputtering Ti to a thickness that may be as large as that of the initial deposit or possibly somewhat thinner. This operation result in the titanium coating being applied to all surfaces, i.e. to the surface of the deposited structural material, to the surface of the portion of the initially deposited transition material that remains and over the exposed portions of the dielectric substrate. In some alternative embodiments operations (7) and (9) may be deleted in favor of using the adhesion layer formed in operation (2)(a).
(10) A plating base or transition layer (e.g. of the sacrificial material, e.g. copper) is deposited over entire substrate (i.e. over the upper surface of the substrate and any materials deposited thereon). The copper plating base provides a transition layer and is generally less than 1-2 microns in thickness and maybe as little as 0.5 microns in thickness or even less. In some alternative embodiments, the transition layer to be deposited need only be applied over the regions etched in operation (6) and as such, if the mask was not removed in operation (8), the transition layer may be deposited with the mask in place. In some alternative embodiments, it may be possible to eliminate the application of this transition layer as sufficient adhesion of the sacrificial material deposited by electrodeposition may be sufficient to allow successful structure formation.
(11) A thick layer of sacrificial material is next electrodeposited over the entire substrate and any materials located thereon. The thickness of the deposited sacrificial material is sufficient to allow planarization at a first layer level to occur.
(12) Next, the deposited materials are planarized to reveal distinct locations containing a first layer of structural material (e.g. nickel) and a first layer of sacrificial material (e.g. copper)
(13) Next electrochemical fabrication operations proceed to form a multilayer structure embedded in sacrificial material.
(14) After formation of the structure, the sacrificial material is removed by etching, leaving the structural material and any uncovered translation layer and/or adhesion layer material.
(15) Finally, the exposed adhesion layer material is removed by etching to yield a multilayer structure adhered to a dielectric substrate via an adhesion layer and a transition layer of material which extends beyond the base of the structural material to form a conductive pad which may, for example, be used as a bonding pad for electrical leads or as a contact pad for a switch.

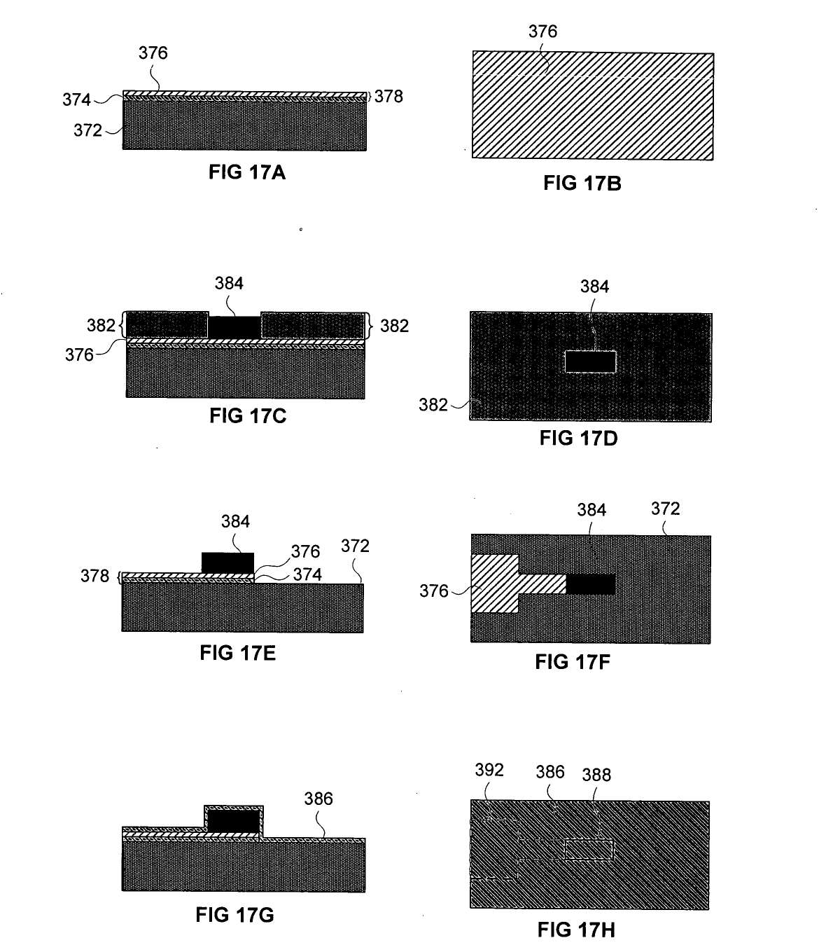

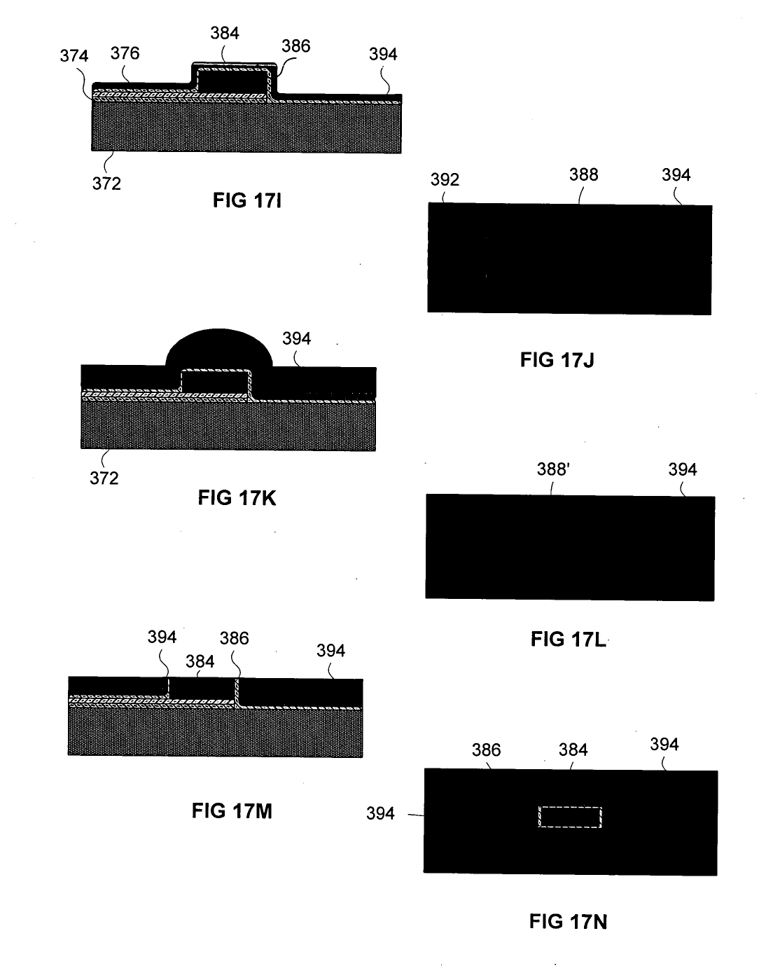

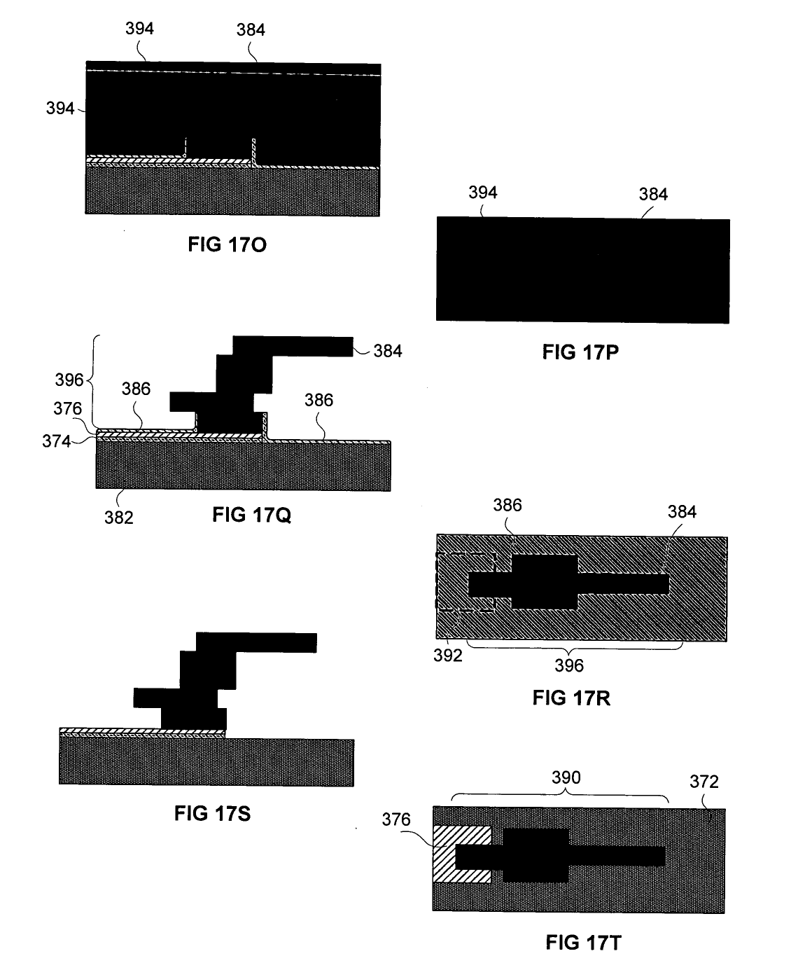

FIGS. 17A-17V schematically depict side views and top views illustrating various states of a process for forming a multilayer structure on a dielectric substrate according to an eleventh embodiment of the invention where the process produces a contact or bonding pad formed out of a transition layer material that was initially part of a seed layer formed on the substrate.

FIG. 17A shows the schematic illustration of a side view of the state of the process of forming a multi-layer structure after a dielectric substrate 372 is obtained and a thin adhesion layer 374 deposited thereon and then a thin transition layer 376 deposited on top of the adhesion layer. The adhesion layer and transition layer together form seed layer 378.

FIG. 17B provides a schematic illustration of a top view of the state of the process shown in FIG. 17A wherein only the transition layer 376 is visible.

FIG. 17C shows the state of the process after a mask 382 is applied to the surface of transition layer 376 and after a deposition 384 of a structural material occurs.

FIG. 17D depicts a top view of the structure of FIG. 17C where the mask material 382 and the conductive structural material 384 can be seen.

FIG. 17E depicts the state of the process after a number of operations have occurred. The structure of FIG. 17E results from the removal of mask 382. Application and patterning of a subsequent mask is used to form a protective coating over a portion of transition layer 376. Etching of exposed transition layer material and adhesion layer material causes their removal after the protective mask is removed. FIG. 17E indicates that the seed layer to the left of structure 384 remains in place due to the shielding provided by a mask while the rest of seed layer 378 was removed so that the surface of the dielectric substrate became exposed.

FIG. 17F depicts a top view of the structure of FIG. 17E where remaining portions of transition layer 376 can be seen to the left of structure 384 and where the upper surface of the dielectric substrate 372 can be seen.

FIG. 17G depicts a state of the process after deposition of a thin adhesion layer has been made so that the adhesion layer covers the entire surface of the substrate and any materials located thereon. The deposition of the adhesion layer of FIG. 17G corresponds to operation 9 as set forth above.

FIG. 17H depicts a top view of the structure of FIG. 17G where only adhesion layer material 386 is shown as existing on the surface of the substrate. Line 388 indicates the position of structural material 384 located below the adhesion layer material. Dash line 392 indicates the outline of the location of the initial transition layer 376 located below the just deposited adhesion layer 386.

FIG. 17I depicts the state of the process after operation 10 deposits a plating base or transition layer formed from a sacrificial material 394. The transition layer 394 is located above adhesion layer 386 which overlays substrate 372 structural material 384 and adhesion layer 374.

FIG. 17J depicts a top view of the structure of FIG. 171 where only material 394 is visible. As with FIG. 17H the region of transitional material 376 is shown by dashed boundary line 392 and the location of structural material 384 is shown by boundary 388.

FIG. 17K depicts a state of the process after a thick deposit of sacrificial material 394 occurs.

FIG. 17L depicts the structure of FIG. 17K where only the sacrificial material 394 can be seen and where dashed boundary 388′ indicates where the structural material 384 is located below the sacrificial material.

FIG. 17M depicts a side view of the structure after completion of operation 12 which planarizes the surface such that both sacrificial material 394, structural material 384, adhesion layer 386 and the transition layer formed from sacrificial material 394 can be seen extending from the upper surface of the structure.

FIG. 17N depicts the structure of FIG. 17M where sacrificial material 394 surrounds adhesion layer 386 and structural material 384.

FIG. 17O depicts a side view of the state of the process after multiple layers of the structure have been formed where each layer includes regions of sacrificial material 394 and regions of structural material 384.

FIG. 17P depicts a top view of the uppermost layer of the structure where a region of structural material 384 can be seen along with a region of sacrificial material 394.

FIG. 17Q depicts a state of the process after the sacrificial material 394 has been removed leaving a structure 396 of conductive structural material 384 resting on transition layer 376 which in turn sits on adhesion layer 374. Additionally adhesion layer 386 is also shown residing above the substrate and above transition layer 376 and working its way up the sides of the first layer of structure 396.

FIG. 17R depicts a top view of the structure 396 where several layers of the structure can be seen located above the adhesion layer material 386 and wherein dashed boundary 392 indicates the perimeter of the region occupied by transition layer 376.

FIG. 17S depicts the state of the process after adhesion layer 386 has been removed wherein the structure 396 can be seen along with transition layer material 376 and the exposed surface of the substrate 372.

FIG. 17T depicts a top view where the structure 390 is seen along with the transition layer material 376 and the exposed surface of the substrate 372.

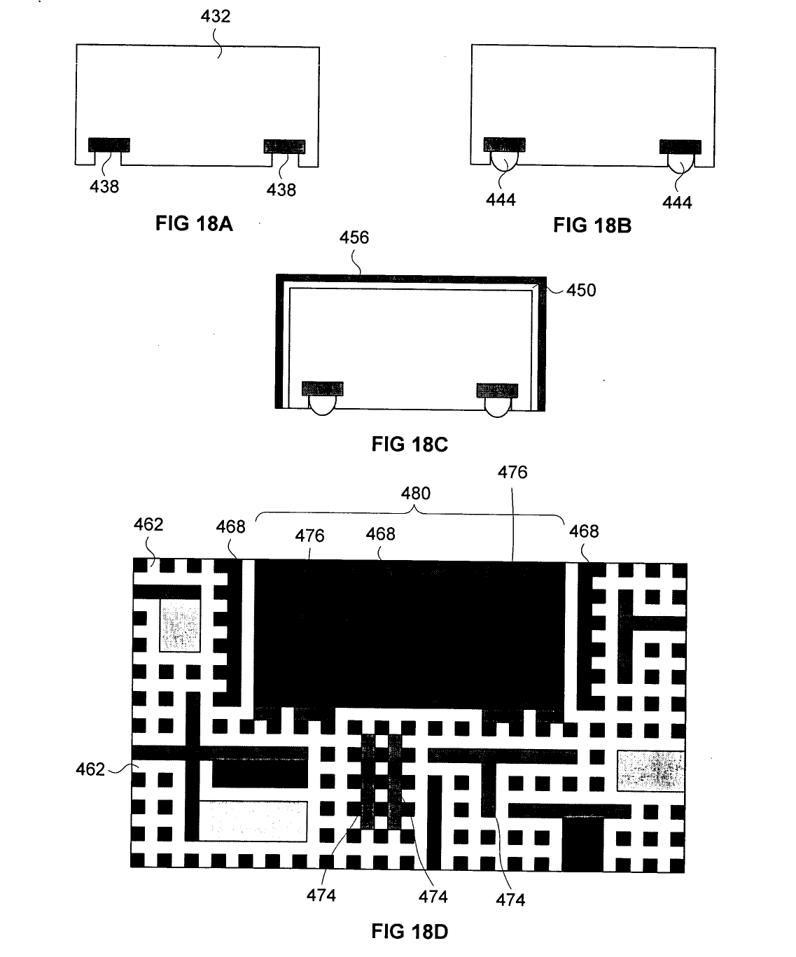

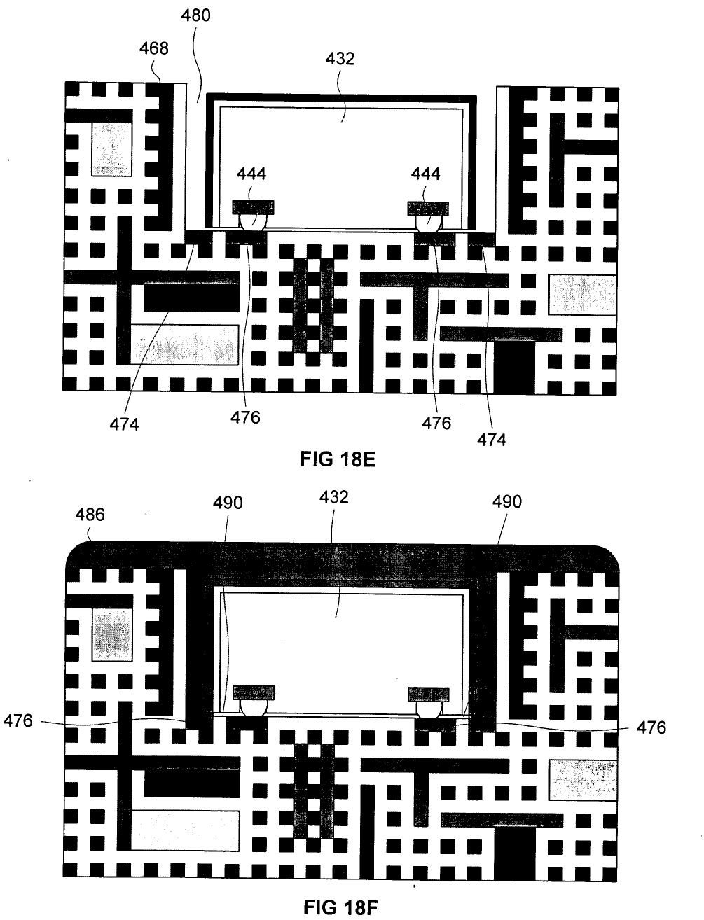

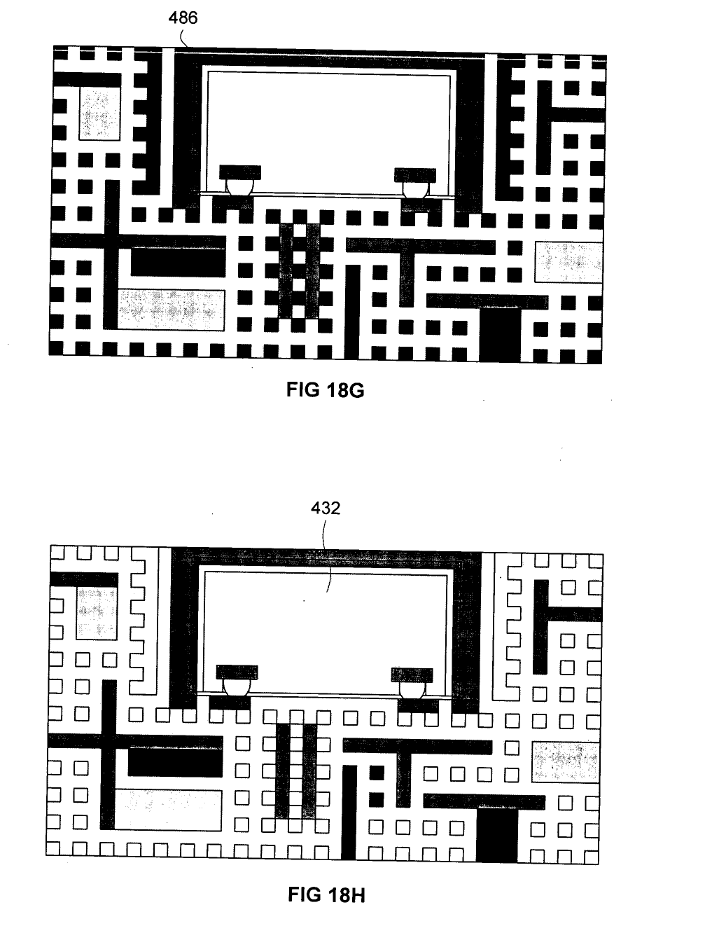

A twelfth embodiment of the invention provides a method for incorporating both a dielectric and an externally fabricated device or structure (i.e. a non-electrochemically fabricated structure) into an electrochemical fabrication process. FIGS. 18A-18H schematically depict side views of various states of the process of the twelfth embodiment as applied to the formation of a particular structure. In these figures, it is assumed that the externally fabricated structure is an integrated circuit. First, an IC chip 432 as shown in FIG. 18A is prepared by applying a low-temperature solder 444 (or a conductive resin) to the bonding pads 438 as shown in FIG. 18B. Then the chip 432 is optionally coated with a polymer passivation layer 450 (e.g., polyimide) to protect it (if desired), and then coated with a layer of metal 456 (which may be the same as other conductive structural metals used in electrochemical fabrication process) as shown in FIG. 18C. FIG. 18D shows a sectional cut through an electrochemically fabricated, unreleased, multilayer device. As can be seen, the device includes a dielectric lattice 462 and a complementary lattice of sacrificial metal 468, which interpenetrates it in much the same manner as discussed above in association with FIGS. 12A-13D. Interconnects and a pair of capacitor plates 474 made of conductor metal are visible, as are deposits of other materials. The product has been designed in 3-D CAD to accept this particular chip, and a cavity 480, temporarily filled with sacrificial metal 468, awaits insertion of the chip. In FIG. 18E the cavity 480 has been etched and the chip 432 inserted (the other sacrificial metal 468 is not yet etched, as it is protected within the cavity walls by a surface layer of solid dielectric and conductive structural material. The sides and top of the device may also be protected by such a wall of dielectric material or alternatively the etching operations may be limited to operate within the cavity 480. If the top most layer is provide with the solid barrier of dielectric material, it may be eventually removed by a lapping operation or other planarization operation. The solder 444 is melted by standard SMT reflow methods, making electrical contact with interconnects 476 at the bottom of the cavity 480. The process of reflowing the solder may be accompanied by a downward pressure on the chip and the bottom of the chip or the bottom surface of the cavity may incorporate a perimeter ring 490 of conformable dielectric material or meltable dielectric material that may form a seal around between the perimeter of the chip and the base of the cavity (to ensure no inadvertent ingress of conductive material between the bottom of the cavity and the chip which could result in a shorting the chip. In alternative embodiments, after attaching the chip and the partially formed device, subsequent plating operations may occur with the device held upside down and only partially immersed in a plating bath which could result in formation of a sealing deposit of conductive structural material without risk of conductive material shorting the chip. Next, as shown in FIG. 18F, conductive structural material 486 (e.g. a desired metal) has been plated over the entire device and chip 432. This metal 486 fills the space surrounding the chip 432 and may establish (as shown) contact with metal 474 on the bottom of the cavity 480. Alternatively the metal 486 may establish contact with conductive metal on the sides of the cavity 480. This metal 486 serves several functions: it establishes a conductive surface above the chip 432 (assuming chip 432 is right side up) so that the electrochemical fabrication process can continue; it encapsulates and protects the chip; and it serves to conduct heat away from the chip. In FIG. 18G this metal 486 and the upper surface of the partially formed structure have been lapped to be flush. At this point, the product is returned to the electrochemical fabrication process for deposition of additional layers of material. After all layers are deposited, the sacrificial material is etched, leaving a completed device containing an integrated circuit or other component enclosed in a dielectric grid and potentially containing various electrochemically fabricated structures within the grid, above the grid (none shown) or beside the grid (none shown). The portion of the product or device containing the chip 432 is shown in FIG. 18H.

After removal of sacrificial metal, optional infiltration of the dielectric lattice is possible. In some embodiments, infiltration may occur via capillary forces drawing a curable liquid dielectric into the pores of the lattice. Additionally, and/or in other embodiments, infiltration may be performed in vacuum.

Some embodiments may employ mask based selective etching operations in conjunction with blanket deposition operations. Some embodiments may form structures on a layer-by-layer base but deviate from a strict planar layer on planar layer build up process in favor of a process that interlacing material between the layers. Such alternating build processes are disclosed in U.S. application Ser. No. 10/434,519, filed on May 7, 2003, entitled Methods of and Apparatus for Electrochemically Fabricating Structures Via Interlaced Layers or Via Selective Etching and Filling of Voids which is herein incorporated by reference as if set forth in full.

Some embodiments may employ diffusion bonding or the like to enhance adhesion between successive layers of material. Various teachings concerning the use of diffusion bonding in electrochemical fabrication process is set forth in U.S. Patent Application No. 60/534,204, filed Dec. 31, 2003 by Cohen et al. which is entitled “Method for Fabricating Three-Dimensional Structures Including Surface Treatment of a First Material in Preparation for Deposition of a Second Material” and which is hereby incorporated herein by reference as if set forth in full.

Further teachings about planarizing layers and setting layers thicknesses and the like are set forth in the following U.S. Patent Applications which were filed on Dec. 31, 2003: (1) U.S. Patent Application No. 60/534,159 by Cohen et al. and which is entitled “Electrochemical Fabrication Methods for Producing Multilayer Structures Including the use of Diamond Machining in the Planarization of Deposits of Material” and (2) U.S. Patent Application No. 60/534,183 by Cohen et al. and which is entitled “Method and Apparatus for Maintaining Parallelism of Layers and/or Achieving Desired Thicknesses of Layers During the Electrochemical Fabrication of Structures”. Still further teachings are found in concurrently filed US Patent Application No. XX/XXX,XXX (corresponding to Microfabrica Docket No. P-US132-A-MF) by Cohen et al. and which is entitled “Method and Apparatus for Maintaining Parallelism of Layers and/or Achieving Desired Thicknesses of Layers During the Electrochemical Fabrication of Structures”. These patent filings are each hereby incorporated herein by reference as if set forth in full herein.

Additional teachings concerning the formation of structures on dielectric substrates and/or the formation of structures that incorporate dielectric materials into the formation process and possibility into the final structures as formed are set forth in a number of patent applications: (1) U.S. Patent Application No. 60/534,184, by Cohen, which as filed on Dec. 31, 2003, and which is entitled “Electrochemical Fabrication Methods Incorporating Dielectric Materials and/or Using Dielectric Substrates”; (2) U.S. Patent Application No. 60/533,932, by Cohen, which was filed on Dec. 31, 2003, and which is entitled “Electrochemical Fabrication Methods Using Dielectric Substrates”; (3) U.S. Patent Application No. 60/534,157, by Lockard et al., which was filed on Dec. 31, 2004, and which is entitled “Electrochemical Fabrication Methods Incorporating Dielectric Materials”; (4) U.S. Patent Application No. 60/574,733, by Lockard et al., which was filed on May 26, 2004, and which is entitled “Methods for Electrochemically Fabricating Structures Using Adhered Masks, Incorporating Dielectric Sheets, and/or Seed Layers that are Partially Removed Via Planarization”; and U.S. Patent Application No. 60/533,895, by Lembrikov et al., which was filed on Dec. 31, 2003, and which is entitled “Electrochemical Fabrication Method for Producing Multi-layer Three-Dimensional Structures on a Porous Dielectric”. These patent filings are each hereby incorporated herein by reference as if set forth in full herein.

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may involve the selective deposition of a plurality of different materials on a single layer or on different layers. Some embodiments may use selective deposition processes or blanket deposition processes on some layers that are not electrodeposition processes. Some embodiments may use nickel as a structural material while other embodiments may use different materials. Some embodiments may use copper as the structural material with or without a sacrificial material. Some embodiments may remove a sacrificial material while other embodiments may not. In some embodiments the anode (used during electrodeposition) may be different from a conformable contact mask support and the support may be a porous structure or other perforated structure. Some embodiments may use multiple conformable contact masks with different patterns so as to deposit different selective patterns of material on different layers and/or on different portions of a single layer.

Many other alternative embodiments will be apparent to those of skill in the art upon reviewing the teachings herein. Further embodiments may be formed from a combination of the various teachings explicitly set forth in the body of this application. Even further embodiments may be formed by combining the teachings set forth explicitly herein with teachings set forth in the various applications and patents referenced herein, each of which is incorporated herein by reference.

In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

1. A fabrication process for forming a multi-layer three-dimensional structure that comprises at least one conductive structural material and at least one dielectric material, comprising:
(a) forming and adhering a layer of material to a previously formed layer and/or to a substrate, wherein the layer comprises a desired pattern of at least one structural material, a grid pattern of a dielectric material, and a gird pattern of a conductive sacrificial material; and
(b) repeating the forming and adhering operation of (a) a plurality of times to build up the three-dimensional structure from a plurality of adhered layers.

2. The process of claim 1 wherein the grid pattern of dielectric material is formed, at least in part, by an electrophoretic deposition operation.

3. The process of claim 1 wherein the formation of the layer additionally comprises at least one planarization operation.

4. The process of claim 1 wherein the formation of at least one of the desired pattern of the conductive structural material, the grid pattern of the dielectric material, and/or the grid pattern of the conductive sacrificial material is formed via a selective deposition operation that deposited material into openings in an adhered mask.

5. A fabrication process for forming a multi-layer three-dimensional structure that comprises at least one conductive structural material and at least one dielectric material, comprising:
(a) forming and adhering a layer of material to a previously formed layer and/or to a substrate, wherein the layer comprises a desired pattern of at least one structural material, a desired pattern of a dielectric material, and a desired pattern of a conductive sacrificial material; and
(b) repeating the forming and adhering operation of (a) a plurality of times to build up the three-dimensional structure from a plurality of adhered layers;
wherein the dielectric material is deposited via an electrophoretic deposition operation.

6. The process of claim 5 wherein the formation of the layer additionally comprises at least one planarization operation.

7. The process of claim 5 wherein the formation of at least one of the desired pattern of the conductive structural material, the desired pattern of the dielectric material, and/or the desired pattern of the conductive sacrificial material is formed via a selective deposition operation that deposited material into openings in an adhered mask.

8. A fabrication process for forming a multi-layer three-dimensional structure on a dielectric substrate, comprising:
(a) depositing a first adhesion layer onto the substrate and a first seed layer onto the first adhesion layer;
(b) using an adhered mask, selectively depositing and adhering a conductive structural material to a selected portion of the seed layer material;
(c) removing only a portion of seed layer material and adhesion layer material that is not coated over by the structural material;
(d) blanket depositing a second adhesion layer material and a second seed layer material over the substrate, exposed portion of the first seed layer material, and the structural material;
(e) blanket depositing sacrificial material;
(f) planarizing the deposited materials to set the height of a first layer and to expose the structural material;
(g) forming additional layers of the structure; and
(h) releasing the structural material from the sacrificial material and removing the second seed layer and the second adhesion layer to reveal the completed structure.

9. A fabrication process for forming a multi-layer three-dimensional structure wherein at least three materials are used in the formation of the structure, comprising:
(a) forming and adhering a first layer of material to the substrate via at least one seed layer material and/or at least one adhesion layer material, wherein the first layer comprises at least one region of a structural material and at least one region of a sacrificial material;
(b) forming a subsequent layer from a plurality of materials that are adhered to previously deposited materials and repeating formation of subsequent layers until the structure is formed from a plurality of adhered layers;
wherein the at least one seed layer material and/or the at least one adhesion layer material separating at least a portion of the structural material of the first layer from the dielectric substrate is different from a seed layer material and/or an adhesion layer material that separates at least a portion of the sacrificial material of the first layer from the dielectric material of the substrate,
wherein at least one of a structural material or at least one of a sacrificial material is selectively patterned using an adhered mask.
